(19) United States
(12) Patent Application Publication
(10) Pub. No.: US 2011/0180891 A1
(43) Pub. Date: Jul. 28, 2011

(54) CONDUCTOR PACKAGE STRUCTURE AND METHOD OF THE SAME

(75) Inventors: Diann-Fang Lin, Zhubei City (TW); Yu-Shan Hu, Yangmei Township (TW)

(73) Assignee: Advanced Chip Engineering Technology Inc.

(21) Appl. No.: 12/869,001

(22) Filed: Aug. 26, 2010

Related U.S. Application Data
(63) Continuation-in-part of application No. 12/536,546, filed on Aug. 6, 2009.

(51) Int. Cl. H01L 31/0232

(52) U.S. Cl. 257/432; 257/E31.127

(57) ABSTRACT

The present invention provides a conductor package structure comprising an optical sensor element. A filling material is filled around the optical sensor element. At least one conductor element is formed through the filling material from top side to the back side for signal connection. A redistribution layer is formed on the at least one conductor element and coupled to die pad of the optical sensor element. A transparent material is formed on the redistribution layer.

### RELATED APPLICATIONS

The present application is a Continuation-in-Part (CIP) of U.S. application Ser. No. 12/536,546 filed on Aug. 6, 2009 for “Conductor Package Structure and Method of the Same,” herein fully incorporated by reference.

### FIELD OF THE INVENTION

This invention relates to a structure of a package, and more particularly to a conductor package structure with signal channels.

### BACKGROUND OF THE INVENTION

### Description of the Prior Art

In the field of semiconductor devices, the device density is increased and the device dimension is reduced, continuously. The demand for the packaging or interconnecting techniques in such high density devices is also increased to fit the situation mentioned above. Conventionally, in the flip-chip attachment method, an array of solder bumps is formed on the surface of the die. The formation of the solder bumps may be carried out by using a solder composite material through a solder mask for producing a desired pattern of solder bumps. The function of chip package includes power distribution, signal distribution, heat dissipation, protection and support . . . and so on. As a semiconductor become more complicated, the traditional package technique, for example lead frame package, flex package, rigid package technique, cannot meet the demand of producing a smaller chip with high density elements on the chip.

Typically, the semiconductor devices require protection from moisture and mechanical damage. The structure involves the technology of a package. In the technology, the semiconductor dies or chips are usually individually packaged in a plastic or ceramic package. The package is required to protect the die and spread the heat generated by the devices. Therefore, the heat dissipation is very important in the semiconductor devices, particularly as the power and the performance of the device increase.

Furthermore, because conventional package technologies have to divide a dice on a wafer into respective dies and then package the die respectively, these techniques are time consuming for a manufacturing process. The chip package technique is highly influenced by the development of integrated circuits. Therefore, as the size of electronics has become demanding, so does the package technique. For the reasons mentioned above, today's trend of package technique is toward ball grid array (BGA), flip chip (FC-BGA), chip scale package (CSP), and wafer level package (WLP). “Wafer level package” is to be understood as meaning that the entire packaging and all the interconnections on the wafer as well as other processing steps are carried out before the singulation (dicing) into chips (dice). Generally, after completion of all assembling processes or packaging processes, individual semiconductor packages are separated from a wafer having a plurality of semiconductor dies. The wafer level package has extremely small dimensions combined with extremely good electrical properties.

WLP technique is an advanced packaging technology, by which the die are manufactured and tested on the wafer, and then singulated by dicing for assembly in a surface-mount line. The wafer level package technique utilizes the whole wafer as one object, not utilizing a single chip or die. Therefore, before performing a scribing process, packaging and testing has been accomplished. Furthermore, WLP is such an advanced technique that the process of wire bonding, die mount and under-fill can be omitted. By utilizing WLP technique, the cost and manufacturing time can be reduced, and the resulting structure of WLP can be equal to the die. Therefore, this technique can meet the demands of miniaturization of electronic devices.

Though there are many advantages of WLP technique mentioned above, some issues still exist that influence the acceptance of WLP technique. For example, although utilizing WLP technique can reduce the CTE mismatch between IC and the interconnecting substrate, as the size of the device minimizes, the CTE difference between the materials of a structure of WLP becomes another critical factor to mechanical instability of the structure. Furthermore, in this wafer-level chip-scale package, a plurality of bond pads formed on the semiconductor die is redistributed through conventional redistribution processes involving a redistribution layer into a plurality of metal pads in an area array type. Solder balls are directly fused on the metal pads, which are formed in the area array type by means of the redistribution process. Typically, all of the stacked redistribution layers are formed over the built-up layer over the die. Therefore, the thickness of the package is increased. This may conflict with the demand of reducing the size of a chip.

Therefore, the present invention provides a conductor package structure to reduce the package thickness to overcome the aforementioned problem and also provide a better board level reliability test of temperature cycling.

### SUMMARY OF THE INVENTION

The present invention provides a conductor package structure that comprises an optical sensor element. A filling material is filled around the optical sensor element. At least one conductor element is formed through the filling material from top side to the back side for signal connection. A redistribution layer is formed on the at least one conductor element and couple to a die pad of the optical sensor element. A transparent material is formed on the redistribution layer.

Wherein the top side of said optical sensor element comprises an image area and an electric contact area in the peripheral area and a plurality of micro lenses formed on the image area. The structure further comprises a protective layer formed on the micro lenses. Wherein the top side of the filling material could be higher than the top side of the optical sensor element and cover the edge area of the top side of the optical sensor element and expose the electric contact area. The conductor package structure further comprises an adhesive layer formed under the optical sensor element. The conductor package structure further comprises a conductive layer formed under the adhesive layer, the filling material and coupled to the conductor element. The conductor package structure further comprises solder bumps/balls formed under the conductive layer for signal connection. The conductor package structure further comprises a metal layer formed on the backside of the optical sensor element. The conductor package structure further comprises a conductive layer formed under the adhesive layer. The conductor package structure further comprises solder bumps/balls formed under the conductor element for signal connection. The conductor package structure further comprises a dielectric layer formed on the filling material which has a first opening formed on said image area. The conductor package structure further comprises an attach material formed on the redistribution layer which has a first opening formed on the image area. Wherein the material of the redistribution layer is the same with that of the attach material. The conductor package structure further comprises a sealing layer to cover said redistribution layer.

### BRIEF DESCRIPTION OF THE DRAWINGS

FIG. 1 illustrates a cross-sectional view of a basic conductor package structure in accordance with one embodiment of the present invention.

FIG. 2 illustrates a cross-sectional view of a downward conductor package structure with signal channels in accordance with one embodiment of the present invention.

FIG. 3 illustrates a cross-sectional view of another downward conductor package structure with signal channels in accordance with one embodiment of the present invention.

FIG. 4 illustrates a cross-sectional view of a dual-side conductor package structure with signal channels in accordance with one embodiment of the present invention.

FIGS. 5-10 illustrate cross-sectional views of processes of making an individual conductor package structure in accordance with one embodiment of the present invention.

FIGS. 11-17 illustrate cross-sectional views of another conductor package structure with signal channels in accordance with some embodiments of the present invention.

### DESCRIPTION OF THE PREFERRED EMBODIMENT

The invention will now be described in greater detail with preferred embodiments of the invention and illustrations attached. Nevertheless, it should be recognized that the preferred embodiments of the invention is only for illustration. Besides the preferred embodiment mentioned here, the present invention can be practiced in a wide range of other embodiments besides those explicitly described, and the scope of the present invention is expressly not limited except as specified in the accompanying claims.

The present invention discloses a conductor package structure utilizing a conductive base having predetermined die through holes and a plurality of openings passing through the conductive base. Signal channels are formed over an electronic element and via connectors, and thereby connecting between the electronic element and via connectors. A marking layer is formed over the signal channels.

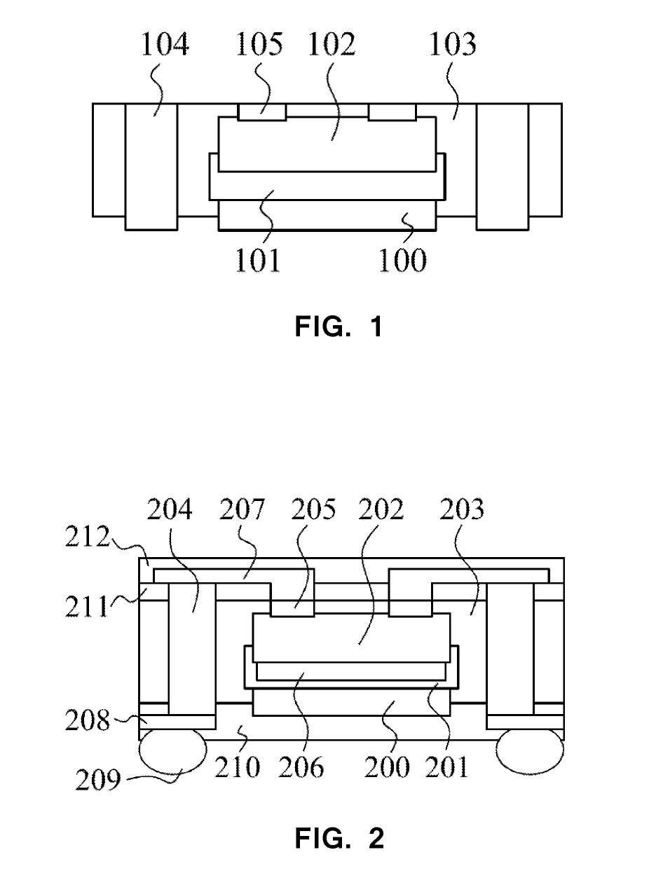

FIG. 1 illustrates a cross-sectional view of a basic conductor package structure in accordance with one embodiment of the present invention. As shown in the FIG. 1, the conductor package structure includes a substrate having predetermined die through holes and a plurality of openings passing through the substrate, wherein the die through hole is to receive a die 102 with die pads 105 formed thereon. In one embodiment, the substrate includes conductive base 100 and conductors 104, wherein the conductive base 100 is formed between the conductors 104, and the bottom of the conductors 104 and the bottom of the conductive base 100 are coplanar. The material of the substrate includes alloy or metal. The alloy includes Alloy42 (42% Ni-58% Fe) or Kovar (29% Ni-17% Co-54% Fe). Preferably, the die 102 is an electronic element. The material of the conductive base 100 includes alloy or metal. Pluralities of the plurality of openings are created through the conductive base 100 from upper surface to lower surface of the conductive base 100. An adhesive layer (material) 101 is formed over the conductive base 100 for adhering the die 102. For example, the adhesive layer 101 comprises conductive material for electric conduction. Conductors 104 are formed between the surface of a filling material 103 passing through the filling material 103, wherein the conductors 104 comprise at least one material for signal connection (electrical communication). The filling material 103 is filled into the space (plurality of openings) between the electronic element 102 and the conductors 104. The filling material 103 is adjacent to the side wall of the electronic element 102 and the conductive base 100, and covering the active side of the electronic element 102. For example, the filling material 103 is surrounded by the conductive base 100, electronic element 102 and the conductors 104.

FIG. 2 illustrates a cross-sectional view of a downward conductor package structure with signal channels in accordance with one embodiment of the present invention. As shown in FIG. 2, the downward conductor package structure includes a substrate consisting of conductive base 200 and conductors 204, wherein the conductive base 200 is formed between the conductors 204 and the bottom of the conductors 204 and the bottom of the conductive base 200 are coplanar. An adhesive layer (material) 201 is formed over the conductive base 200 for adhering a die 202. Preferably, the die 202 is an electronic element. For example, the adhesive layer 201 comprises conductive material. Conductors 204 are formed between the surface of a filling material 203 passing through the filling material 203, wherein the conductors 204 comprise at least one material for signal connection (electrical communication). The filling material 203 is filled into the space between the electronic element 202 and the conductors 204. The filling material 203 is adjacent to the side wall of the electronic element 202 and the conductive base 200, and covering the active side of the electronic element 202. For example, the filling material 203 is surrounded by the conductive base 200, electronic element 202 and the conductors 204. Contact pads (signal channels) 208 are located on the lower surface of the conductors 204 and connected to the conductors 204. A dielectric (buffer) layer 211 is formed over the electronic element 202 and the filling material 203, and under signal channels 207, to expose the conductors 204 and pads 205 of the electronic element 202. In one embodiment, the dielectric layer 211 comprises an elastic material, photosensitive material. Signal channels 207, for example redistribution layer (RDL), are formed over (upper surface of) the electronic element 202 and the connectors 204, and thereby connecting between the pads 205 of the electronic element 202 and via connectors 204. A conductive layer 206 is formed between the electronic element 202 and the adhesive layer 201 for electric conduction. A protective layer 210 is formed under the filling material 203 for protection and covering the filling material 203, the conductive base 200, the conductors 204 and the signal channels 208 to expose the signal channels 208. Solder bumps/balls 209 are formed under the signal channels 208 for signal connection. Another protective layer 212 is formed over (upper surface of) the signal channels 207 for protection and covering the dielectric (buffer) layer 211 and the signal channels 207. In one embodiment, material of the protective layers 210, 212 comprises SINR, silicone rubber, and the protective layer 210 may be formed by a molding or gluing method (dispensing or printing).

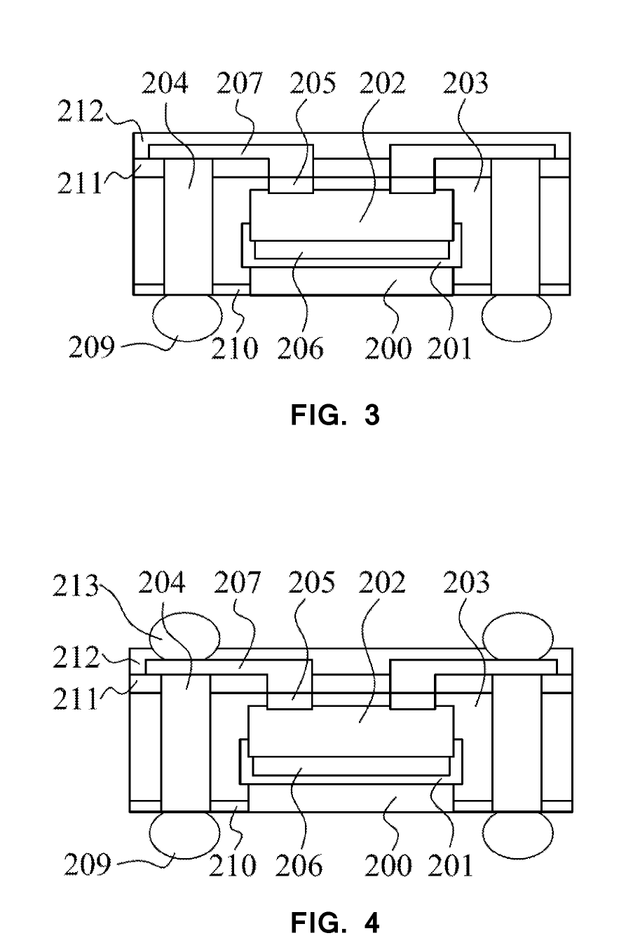

FIG. 3 illustrates a cross-sectional view of another downward conductor package structure with signal channels in accordance with one embodiment of the present invention. As shown in the FIG. 3, the downward conductor package structure omits signal channels 208. The protective layer 210 is formed under the filling material 203 for protection and covering the filling material 203 to expose the connectors 204 and the conductive base 200. Solder bumps/balls 209 are formed under the connectors 204 for signal connection. Most of the parts of the FIG. 3 are similar to FIG. 2; and therefore the detailed descriptions are omitted. In such embodiment, the exposing conductive base 200 can enhance the performance of heat dissipation. In one embodiment, especially, bottom of the conductors 204 has a concave shape portion 204a formed therein for facilitating aligning and receiving with the solder bumps/balls 209 such that the solder bumps/balls 209 may be accurately attached on the conductors 204. The concave shape portion 204a may be formed by a photolithography process and an etching process.

FIG. 4 illustrates a cross-sectional view of a dual-side downward conductor package structure with signal channels in accordance with one embodiment of the present invention. As shown in the FIG. 4, the downward conductor package structure omits signal channels 208. The protective layer 210 is formed under the filling material 203 for protection and covering the filling material 203 to expose the connectors 204 and the conductive base 200. Solder bumps/balls 209 are formed under the connectors 204 for signal connection. The protective layer 212 is formed over (upper surface of) the signal channels 207 for protection and covering the dielectric (buffer) layer 211 and the signal channels 207 to expose the signal channels 207. Solder bumps/balls 213 are formed over the signal channels 207 for signal connection. Most of the parts of the FIG. 4 are similar to FIG. 2; and therefore the detailed descriptions are omitted. In such embodiment, the exposing conductive base 200 can enhance the performance of heat dissipation.

Furthermore, a stacking conductor package structure with signal channels may be applied to the present invention. For example, the stacking conductor package structure comprises a twin side stacking conductor package structure, or an upward stacking conductor package structure.

It should be noted that the thickness of the protective layer (film) is preferably around 0.1 um to 0.3 um and the reflection index close to the air reflection index 1. The materials of the protective layer can be SiO2, Al2O3 or Fluoro-polymer etc.

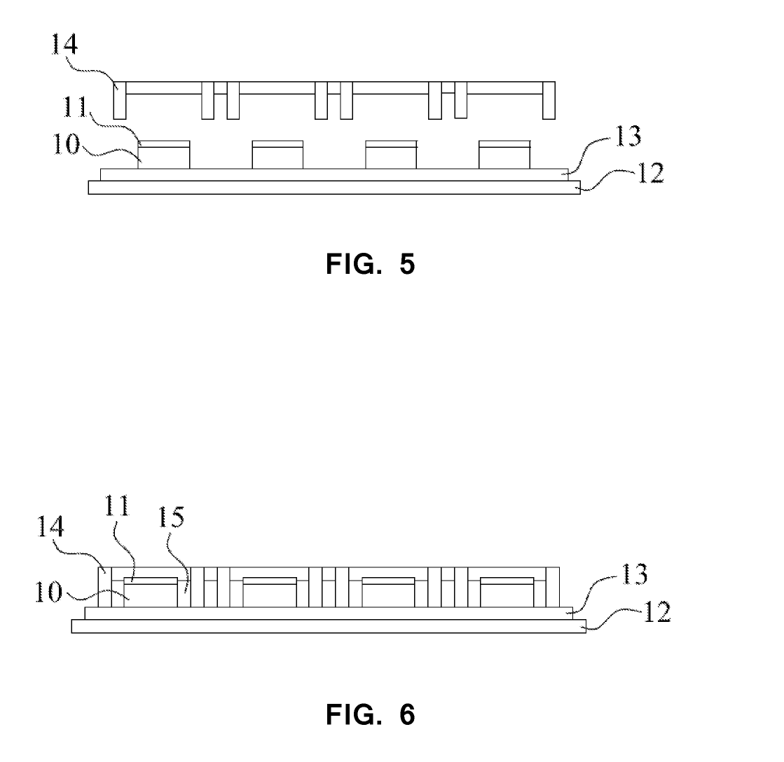

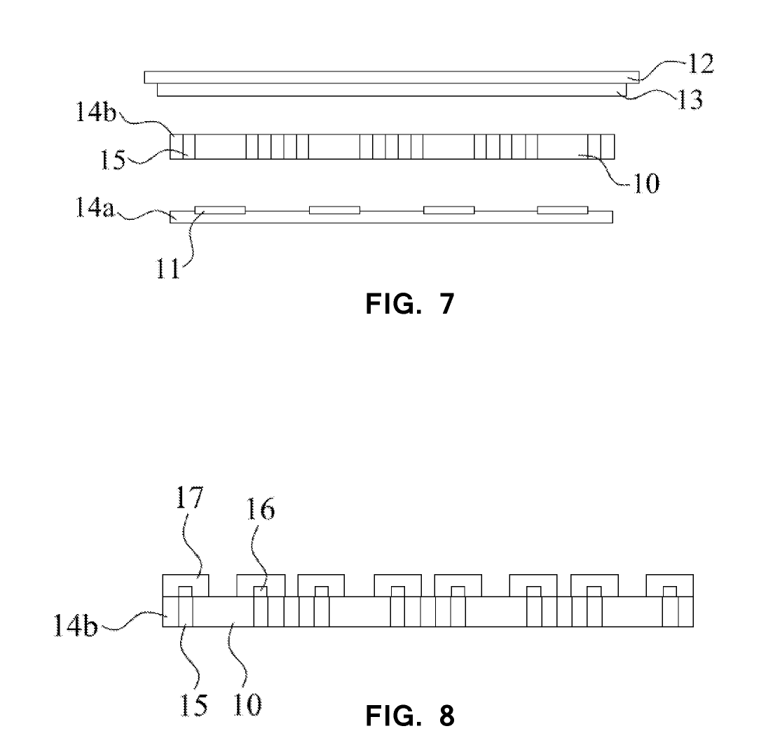

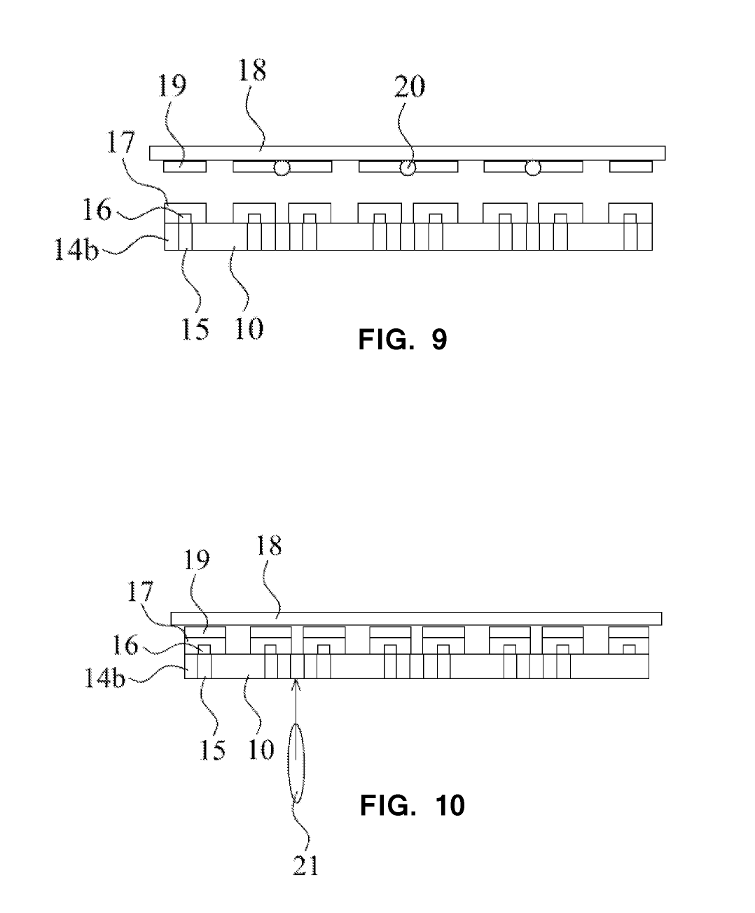

Next, a method for forming a conductor package structure is described. Firstly, referring to FIG. 5, an adhesive layer 13 is formed on a carrier plate 12, and then a plurality of dice 10 are disposed and bonded onto the adhesive layer 13 by a pick and place process. An adhesive material 11 is formed over backside of the dice 10. A mold 14 is prepared above the carrier plate 12. Next, referring to FIG. 6, the mold 14 is pressed on the plurality of dice 10, and thereby mounting on the adhesive material 11, and adhering on the adhesive layer 13. A filling material 15 is filled in the space between the mold 14 and around the plurality of dice 10. Subsequently, referring to FIG. 7, the adhesive layer 13 and the carrier plate 12 are removed from the dice 10 to expose an active area of the dice 10. Then, the adhesive material 11 and part of the mold 14a are removed from the dice 10 to leave remaining mold 14b as conductors adjacent to the filling material 15, wherein thickness of the conductor is depend on product demand. Next, referring to FIG. 8, a dielectric layer 16 is formed over the active side of the dice 10 and the filling material 15 to expose die pad, the conductor and image sensing area of the active side, and then a wiring 17 is formed on the dice 10 and the conductor 14b to couple to die pad and the conductor 14b. The above processes may be formed by a photolithography process and an etching process. Subsequently, referring to FIG. 9, a patterned adhesive layer 19 is formed on an optical base 18, for example optical glass. A sealing layer (encapsulation material) 20 may be optionally formed on the space between the patterned adhesive layer 19 which locates at the peripheral area (such as scribe line) of an individual die package unit. Next, referring to FIG. 10, the optical base 18 is bonded onto the wiring 17 by the patterned adhesive layer 19. Finally, a laser sawing process based on a scribe line 21 is utilized to form an individual die package unit. It is noted that the encapsulation material 20 may be optionally formed before or after the laser sawing process.

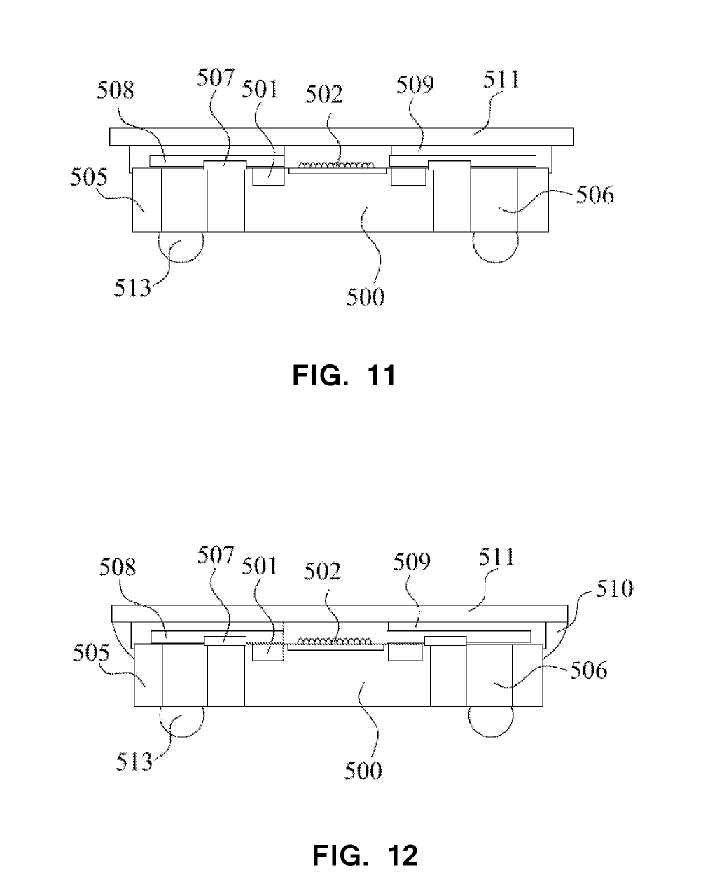

FIG. 11 illustrates a cross section view of an individual conductor package structure in accordance with one embodiment of the present invention. Referring to FIG. 11, the conductor package structure may be manufactured by the above-mentioned processes. A die 500, for example an optical sensor element 500, comprises a top side and a back side opposite to the top side, wherein the top side of the optical sensor element 500 comprises an image area and an electric contact area in the peripheral area, and a plurality of micro lenses 502 are formed on the image area and a die pad 501 is located under the electric contact area; wherein a protection layer is formed on the micro lenses 502. The protective layer includes repellency layer, and material of the repellency layer includes Polycarbonate, Fluor polymer. A filling material 505 is filled around the optical sensor element 500. A conductor element 506 is formed through the filling material 505 from top side to the back side for signal connection (electrical communication). A dielectric layer 507 is formed over the optical sensor element 500 and the filling material 505 with an opening formed on the package body, wherein the opening is formed on the image area. In one embodiment, the dielectric layer 507 comprises an elastic material, photosensitive material. Signal channels 508, for example redistribution layer, are formed over (upper surface of) the conductor element 506 and the dielectric layer 507, and thereby connecting between the die pad 501 of the electric contact area of the optical sensor element 500 and the conductor element 506. An attach material (adhesive layer) 509 is formed on the redistribution layer 508, wherein the material of the redistribution layer 508 may be the same with the material of the attach material 509, wherein the attach material 509 is formed with an opening on the image area. A transparent material (optical base) 511 is formed on the package body and attached to the attach material 509. Solder bumps/balls 513 are formed under the conductor element 506 for signal connection.

In another embodiment, a sealing layer (encapsulation material) 510 may be optionally formed at the peripheral area (such as scribe line) of the package body to cover the attach material 509 before or after the laser sawing process, and thereby enhancing yield and integrity of the sawing, and structural strength of the package body, shown in FIG. 12.

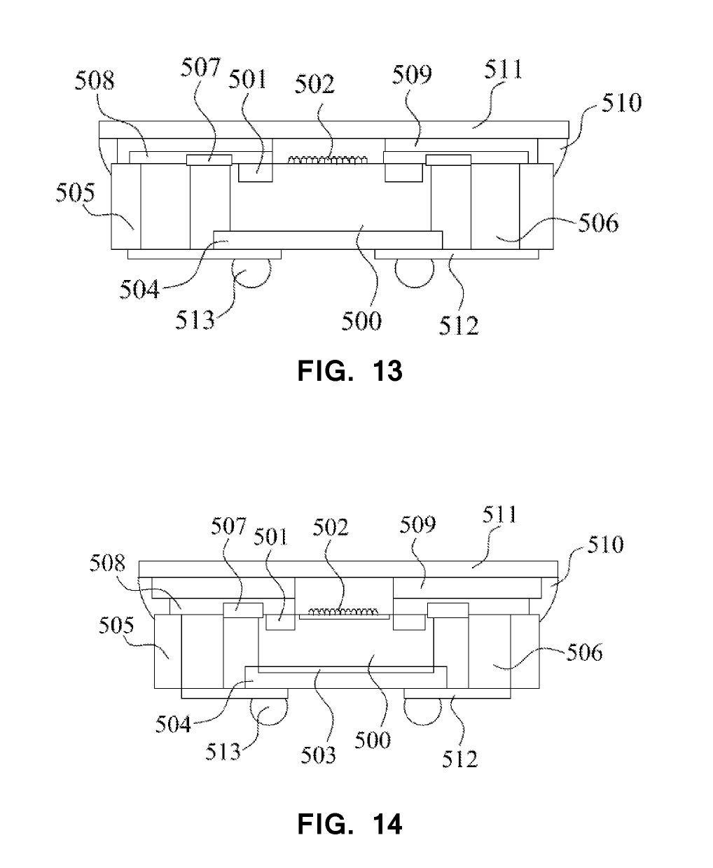

FIG. 13 illustrates a cross-sectional view of another conductor package structure with signal channels in accordance with one embodiment of the present invention. As shown in the FIG. 13, an adhesive layer 504 is formed under the optical sensor element 500 and surrounded by the filling material 505 to expose the filling material 505 for attaching. A metal layer 512 is formed over the adhesive layer 504, the filling material 505 and the conductor element 506, and thereby attaching to the adhesive layer 504 and connecting to the conductor element 506. Solder bumps/balls 513 are formed under the metal layer 512 for signal connection. Most of the parts of the FIG. 13 are similar to FIG. 12; and therefore the detailed descriptions are omitted.

In yet another embodiment, a metal layer 503 may be optionally formed backside of the optical sensor element 500 for heat dissipation, shown in FIG. 14.

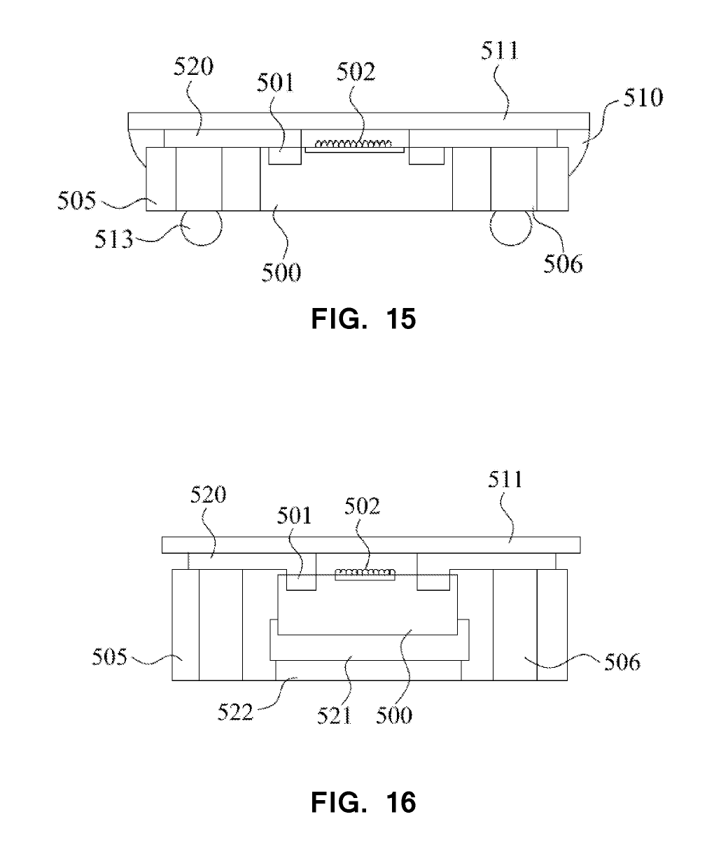

FIG. 15 illustrates a cross-sectional view of an individual conductor package structure in accordance with one embodiment of the present invention. In one embodiment, signal channels 520, for example redistribution layer 520, are formed over the filling material 505, the conductor element 506 and the die pad 501, and thereby connecting between the die pad 501 of the optical sensor element 500 and the conductor element 506. A transparent material (optical base) 511 is formed on the redistribution layer 520, shown in FIG. 15. In this embodiment, there is no need for the dielectric layer 507 and the attach material 509 A sealing layer 510 is formed at the peripheral area of the package body to cover redistribution layer 520.

FIG. 16 illustrates a cross-sectional view of an individual conductor package structure in accordance with one embodiment of the present invention. Similarly, in one embodiment, a redistribution layer 520 is formed over the filling material 505, the conductor element 506 and the die pad 501, and thereby connecting between the die pad 501 of the optical sensor element 500 and the conductor element 506. A transparent material (optical base) 511 is formed on the redistribution layer 520, shown in FIG. 16. In this embodiment, there is no need for the dielectric layer 507 and the attach material 509. Wherein the top side of the filling material 505 could be higher than the top side of the optical sensor element 500 and cover the edge area of the top side of the optical sensor element 500 and expose the electric contact area. An elastic dielectric layer may be optionally formed over the optical sensor element 500 and the filling material 505 with an opening formed on the image area, and wherein material of the elastic dielectric layer may be the same with that of the filling material 505. An adhesive layer 521 is formed under the optical sensor element 500 surrounding by the filling material 505 for attaching, and over a metal layer 522. The metal layer 522 is used to be wiring redistributed, for heat dissipation and EMI shielding, or as an antenna.

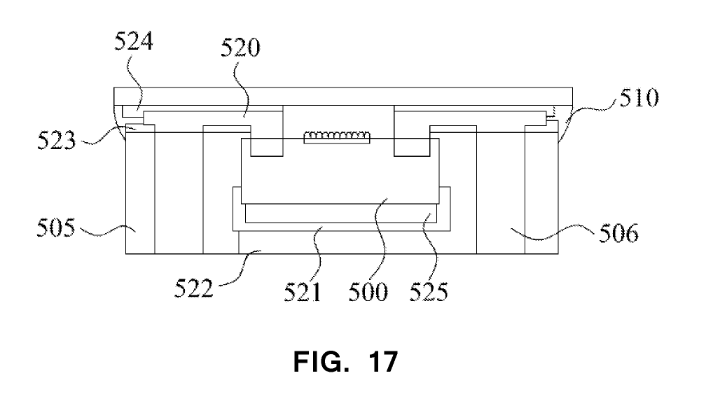

In another embodiment, a sealing layer (encapsulation material) 510 may be optionally formed at the peripheral area of the package body to cover an attach material 524, a dielectric layer 523 and the redistribution layer 520, and thereby enhancing yield and integrity of the sawing, and structural strength of the package body, shown in FIG. 17. A metal layer 525 may be optionally formed backside of the optical sensor element 500 for enhancing adhesion between the adhesive layer 521 and the optical sensor element 500.

The communication traces penetrate through the substrate via the contact through holes, and therefore the thickness of the die package is apparently shrinkage. The package of the present invention will be thinner than the prior art. Further, the substrate is pre-prepared before package. The die through hole and the contact through holes are pre-determined as well. Thus, the throughput will be improved.

Hence, the advantages of the present invention are:

The conductor substrate is pre-prepared with pre-form through hole; it can generates the super thin package due to die insert inside the substrate; it can be used as stress buffer releasing area by filling silicone rubber to absorb the thermal stress due to the CTE difference between silicon die (CTE˜2.3) and the conductor substrate. The packaging throughput will be increased (manufacturing cycle time was reduced) due to application of the simple process. The reliability for both package and board level is better than ever, so no thermal mechanical stress can be applied on the solder bumps/balls. The cost is low and the process is simple. The manufacturing process can be applied fully automatic especially in module assembly. It is easy to form the combo package (dual dice package). It has high yield rate due to particles free, simple process, full automation.

Although preferred embodiments of the present invention have been described, it will be understood by those skilled in the art that the present invention should not be limited to the described preferred embodiments. Rather, various changes and modifications can be made within the spirit and scope of the present invention, as defined by the following claims.

Having described the invention, the following is claimed:

1. A conductor package structure, comprising:
an optical sensor element;
a filling material filled around said optical sensor element;
at least one conductor element formed through said filling material from top side to the back side for signal connection;
a redistribution layer formed on said at least one conductor element and coupled to die pad of said optical sensor element; and
a transparent material formed on said redistribution layer.

2. The structure of claim 1, wherein the top side of said optical sensor element comprises an image area and an electric contact area in the peripheral area and a plurality of micro lenses formed on said image area.

3. The structure of claim 2, further comprising a protective layer formed on said micro lenses.

4. The structure of claim 3, wherein said protective layer includes a repellency layer.

5. The structure of claim 4, wherein material of said repellency layer includes Polycarbonate, Fluor polymer.

6. The structure of claim 2, wherein the top side of said filling material could be higher than the top side of said optical sensor element and cover the edge area of said top side of said optical sensor element and expose said electric contact area.

7. The structure of claim 1, further comprising an adhesive layer formed under said optical sensor element.

8. The structure of claim 7, wherein said adhesive layer comprises conductive material.

9. The structure of claim 7, further comprising a conductive layer formed under said adhesive layer, said filling material and coupled to said conductor element.

10. The structure of claim 9, further comprising solder bumps/balls formed under said conductive layer for signal connection.

11. The structure of claim 10, further comprising a metal layer formed on the backside of said optical sensor element.

12. The structure of claim 7, further comprising a conductive layer formed under said adhesive layer.

13. The structure of claim 1, further comprising solder bumps/balls formed under said conductor element for signal connection.

14. The structure of claim 1, further comprising a dielectric layer formed on said filling material which has a first opening formed on said image area.

15. The structure of claim 1, further comprising an attach material formed on said redistribution layer which has a first opening formed on said image area.

16. The structure of claim 15, wherein the material of said redistribution layer is the same with that of said attach material.

17. The structure of claim 1, further comprising a sealing layer to cover said redistribution layer.
